(19) United States
(12) Patent Application Publication
(10) Pub. No.: US 2008/0297187 A1
(43) Pub. Date: Dec. 4, 2008

(54) LOCATION DEVICE FOR CONTACT PROBES

(75) Inventor: WEN-QI LV, Foshan (CN)

Correspondence Address: PCE INDUSTRY, INC.;ATT. CHENG-JU CHIANG, 458 E. LAMBERT ROAD, FULLERTON, CA, 92835, US

(73) Assignees: PREMIER IMAGE TECHNOLOGY(CHINA) LTD., Foshan City (CN); HON HAI PRECISION INDUSTRY CO., LTD., Tu-Cheng (TW)

(21) Appl. No.: 11/933,944

(22) Filed: Nov. 1, 2007

(30) Foreign Application Priority Data
May 31, 2007 (CN) 200710200734.4

(51) Int. Cl. G01R 1/06

(52) U.S. Cl. 324/758

(57) ABSTRACT

A location device for holding a number of probes is provided. The probes include a body, a first needle and a second needle respectively and coaxially disposed at opposite ends of the body. The location device includes a first support structure, a second support structure overlapping the first support structure and a number of through holes running through the first support structure and the second support structure. Each of the through holes includes a locating hole, a first aperture and a second aperture respectively disposed at opposite ends of and communicated with the locating hole and configured for respectively receiving the first, second needle of the probe. The first, second needle respectively extend out of the first, second aperture. The probes are clamped by the first, second support structure and located by the locating hole of the support device.

### TECHNICAL FIELD

The present invention relates to contact probes for testing electrical circuits and, particularly, to a location device for accurately positioning the contact probes.

### BACKGROUND

Probe cards or testing devices are crucial for efficient manufacture of electronic circuits, these devices enable testing and isolation of defective circuits during production. Probe cards are frequently employed for testing functionality of integrated circuits on wafers before cutting and mounting these integrated circuits inside an IC chip package. The arbitrary position and enormous number of contact pads in such circuits, especially in the very large scale integration domain, impose stringent requirements on probe cards.

To meet these stringent requirements, the probe card's contacting elements, such as probe needles or probes, must be maintained in precise alignment during both the construction and operation of the probe card. Referring to FIG. 4, a typical method for locating probes is shown. Firstly, a data interface 30 having copper foils 301, is provided. Then ends of the probes 31 are bonded to the copper foil 301 via a bonding material. Finally, opposite ends of the probes 31 are held via a support device 32. The support device 32 has a number of locating holes 321 configured for clamping and maintaining the probes 31 at a correct position.

The typical method for locating the probes 31 has two problems. Firstly, during mounting the probe 31 onto the data interface 30, the relatively small size of the probes 31 make it difficult to hold the probe 31 at its proper position. Secondly, the bonding material must be thermally treated to bond adequately with the probes 31, a process called epoxy curing. During this process, the epoxy changes shape slightly, thus moving the probes 31 out of position. Thus, there is a need to mount and affix probes 31 in a manner that ensures proper positioning has been maintained after both the mounting and thermal treating steps have been completed, because it is difficult to reposition the probes 31 after bonding to the data interface 30.

### SUMMARY

In accordance with a present embodiment, a location device for holding a number of probes therein is provided. Each probe includes a body, a first needle and a second needle respectively and coaxially disposed on opposite ends of the body. The location device includes a first support structure, a second support structure overlapping the first support structure and a number of through holes running through the first support structure and the second support structure. Each of the through holes includes a locating hole, a first aperture and a second aperture respectively disposed at opposite ends of and communicate with the locating hole and configured for respectively receiving the first, second needle of the probe. The locating hole is disposed in at least one of the first, second support structures and configured for receiving the body of the probes therein. The first, second needle respectively extend out of the first, second apertures.

### BRIEF DESCRIPTION OF THE DRAWINGS

The present invention is described in detail hereinafter, by way of example only, through description of a preferred embodiment thereof and with reference to the accompanying drawing in which:

FIG. 1 is a schematic cross-section view of a first support structure and a second support structure of a location device according to a first embodiment of the present invention;

FIG. 2 is a schematic cross-section view of the location device of FIG. 1 assembled with a number of probes;

FIG. 3 is a schematic cross-section view of a location device according to a second embodiment of the present invention, together with a number of probes; and

FIG. 4 is a schematic cross-section view of a typical location device and a number of probes.

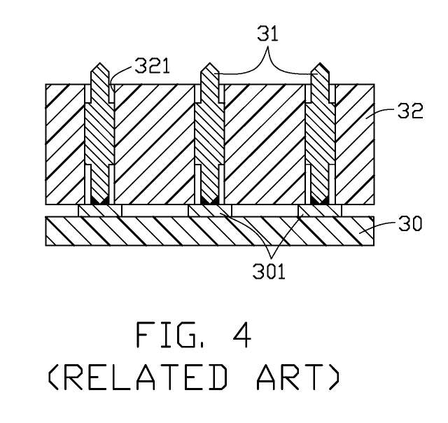

### DETAILED DESCRIPTION OF THE PREFERRED EMBODIMENTS

The detailed explanation of a location device for holding a number of probes therein according to the present invention will now be made with reference to the drawing attached hereto.

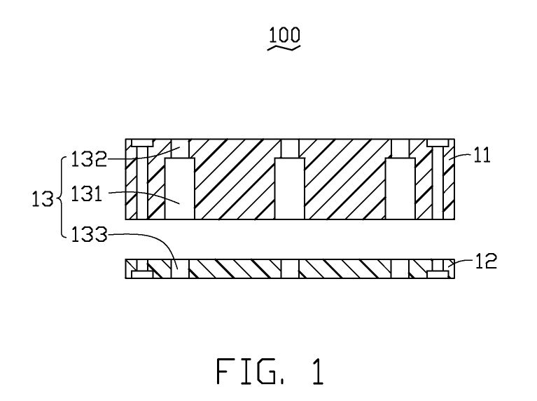

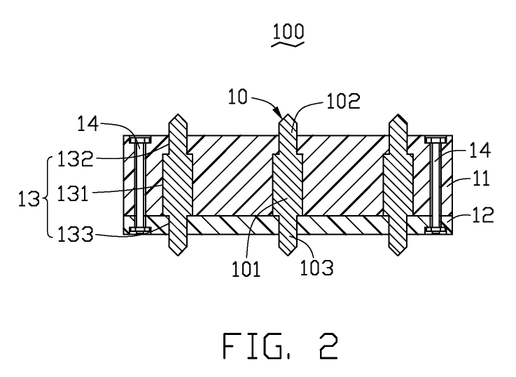

Referring to FIGS. 1-2, a location device 100 for holding probes 10 in position is shown. The location device 100 includes a first support structure 11, a second support structure 12 overlapping the first support structure 11, and a number of through holes 13 running through the first support structure 11 and the second support structure 12 for receiving the probes 10 therein.

Each of the probes 10 includes a body 101, a first needle 102 and a second needle 103 respectively and coaxially extending from opposite ends of the body 101. The first, second needles 102, 103 can be integrally formed with the body 101 and can be also connected with the body 101 via a screw thread. In this embodiment, the first, second needles 102, 103 are integrally formed with the body 101, and the diameter of the body 101 is essentially greater than that of each of the first, second needles 102, 103. The probes 10 can be cylindrical, square, or rectangular. In this embodiment, the probes 10 are solid cylinders. The first, second needles 102, 103 of the probes 10 are respectively configured for contacting a corresponding pad of a PCB (not shown) and a copper foil of a data interface (not shown) to transmit signals between the PCB and the data interface. The probes 10 can be made from conductive material, such as copper, iron or the like.

The first support structure 11 and the second support structure 12 are made from insulative material, such as resin, so as to prevent short circuits among the probes 10. The first support structure 11 can be connected with the second support structure 12 via locking devices 14, thereby clamping the probes 10 between the first, second support structures 11, 12. The locking devices 14 can be screws, pins or the like. In the present embodiment, the locking device 14 is a screw.

Each of the through holes 13 includes a locating hole 131, a first aperture 132 and a second aperture 133. The first, second apertures 132, 133 are respectively defined at opposite ends of and communicate with the locating holes 131. The locating hole 131 is disposed in the first support structure 11 and configured for receiving the body 101 therein. It can be understood that the locating hole 131 can also be disposed in the second support structure 12. The shape and area of the locating hole 131 in cross-section are essentially same as that of the body 101, and a length of the locating hole 131 along the axis of the locating hole 131 is less than or essentially equal to that of the body 101 of the probes 10. The first aperture 132 is disposed in the first support structure 11 and configured for receiving the first needle 102, and its length along an axis of the first aperture 131 is essentially less than that of the first needle 102. Thus, the first needle 102 can extend out of the first aperture 131. The second aperture 133 is disposed in the second support structure 12 and configured for receiving the second needle 103 therein, and its length along the axis of the second aperture 132 is essentially less than that of the second needle 103. Thus, the second needle 103 can extend out of the second aperture 132.

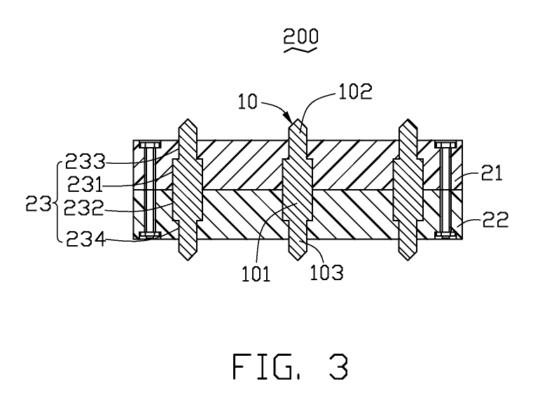

Referring to FIG. 3, a location device 200 for holding probes 10 in position, according to a second preferred embodiment, is shown. The location device 200 includes a first support structure 21, a second support structure 22 overlapping the first support structure 22 and a number of through holes 23 running through the first, second support structure 21, 22 for receiving the probes 10 therein.

Each of the through hole 23 includes a first locating hole 231, a second locating hole 232, a first aperture 233 and a second aperture 234. The first, second apertures 233, 234 are respectively connected to a corresponding end of the first, second locating holes 231, 232. The first locating hole 231 and the first aperture 233 are disposed in the first support structure 21. The second locating hole 232 and the second aperture 234 are disposed in the second support structure 22. The difference between the location device 100 and the location device 200 is that the first, second locating holes 231, 232 are respectively disposed in the first, second support structures 21, 22.

It can be understand that the first support structure 21 may be the same as the second support structure 22 so as to conveniently manufacture and, if needed, replace the first support structure 21 or the second support structure 22.

As described above, the probes are clamped by the first, second support structure and located by the locating holes of the location device.

It can be understood that the above-described embodiment are intended to illustrate rather than limit the invention. Variations may be made to the embodiments and methods without departing from the spirit of the invention. Accordingly, it is appropriate that the appended claims be construed broadly and in a manner consistent with the scope of the invention.

What is claimed is:

1. A location device for holding a plurality of probes therein, each of the probes comprising a body, a first needle and a second needle, the first and second needles being respectively coaxially disposed on opposite ends of the body, comprising:
a first support structure;
a second support structure overlapping the first support structure;
a plurality of through holes running through the first support structure and the second support structure, each of the through holes comprising a locating hole, a first aperture and a second aperture respectively disposed at opposite ends of and communicated with the locating hole and configured for respectively receiving the first, second needles of the probe therein, the locating hole disposed in at least one of the first, second support structures and configured for locating the body of the probes, the first, second needles respectively extending out of the corresponding first, second apertures.

2. The location device as claimed in claim 1, wherein the first support structure is connected with the second support structure via a locking device.

3. The location device as claimed in claim 2, wherein the locking device is a screw.

4. The location device as claimed in claim 2, wherein the locking device is a bolt.

5. The location device as claimed in claim 2, wherein the locking device is a pin.

6. The location device as claimed in claim 1, wherein the shape and area of the locating hole in cross-section are essentially equal to that of the body of the probe, and a length of the locating hole along the axis of the locating hole is less or essentially equal to that of the body of the probe.

7. The location device as claimed in claim 1, wherein the diameter of each of the first, second apertures is less than that of the locating hole.

8. The location device as claimed in claim 1, wherein the locating hole is disposed on one of the first, second support structures.

9. The location device as claimed in claim 1, wherein the locating hole comprises a first locating hole disposed in the first support structure and a second locating hole disposed in the second support structure.

10. The location device as claimed in claim 9, wherein a total length of the first, second locating holes along an axis of the first, second locating holes is essentially equal to that of the body of the probe.

11. The location device as claimed in claim 1, wherein the length of the first, second apertures along an axis of the locating holes is less than that of the first, second needles.

12. The location device as claimed in claim 1, wherein a shape and area of the first, second apertures in cross-section are essentially equal to that of the first, second needles.

13. A location device holding a plurality of probes therein, each of the probes comprising a body, a first needle and a second needle, the first and second needles being respectively coaxially disposed on opposite ends of the body, one shoulder formed at one of two junctions between the body and the first, second needles, the location device comprising:
a first support structure;
a second support structure connected with the first support structure;
a plurality of through holes running through the first support structure and the second support structure, each of the through holes comprising a locating hole, a first aperture and a second aperture respectively disposed at opposite ends of and communicated with the locating hole, the locating hole disposed in at least one of the first and second support structures and configured to locate the body of one probe therein, the first and second apertures being configured for respectively receiving the first and second needles of the probe therein, a step being formed at one of two junctions between the locating hole and the first, second apertures configured to contact with the shoulder of the probe to thereby locate the probe in the corresponding through hole in a length direction of the probe.

14. The location device as claimed in claim 13, wherein the first and second needles respectively extend out of the corresponding first and second apertures in the length direction of the probe.

15. The location device as claimed in claim 14, wherein the first support structure is assembled with the second support structure via a locking device after the probes are received in the through holes.
